(19) United States
(12) Patent Application Publication
(10) Pub. No.: US 2007/0262476 A1
(43) Pub. Date: Nov. 15, 2007

(54) Method for providing STI structures with high coupling ratio in integrated circuit manufacturing

(75) Inventors: Yi Ding, Sunnyvale, CA (US); Jason B. Taylor, Pleasanton, CA (US); Chiliang Chen, Sunnyvale, CA (US)

Correspondence Address: MACPHERSON KWOK CHEN & HEID LLP, 2033 GATEWAY PLACE, SUITE 400, SAN JOSE, CA, 95110, US

(73) Assignee: ProMOS Technologies Pte. Ltd.

(21) Appl. No.: 11/431,223

(22) Filed: May 9, 2006

(51) Int. Cl. H01L 21/8238

(52) U.S. Cl. 257/E21.533; 438/203

(57) ABSTRACT

A process for manufacturing an integrated circuit using shallow trench isolation (STI) includes a 2-step nitride removal process which, when combined with a nitride pull-back step provides, in a floating gate memory integrated circuit, a high coupling ratio and a reduction in thinning of the tunnel oxide layer in a floating gate memory integrated circuit.

### BACKGROUND OF THE INVENTION

1. Field of the Invention

The present invention relates to shallow trench isolation (STI) structures used in integrated circuits. In particular, the present invention relates to process methods in manufacturing such STI structures.

2. Discussion of the Related Art

A floating gate nonvolatile memory cell stores information by storing an electrical charge on its floating gate. The floating gate is capacitively coupled to the control gate. In order to write the cell, a potential difference is created between the control gate and some other region, for example, the source, drain or channel region of the cell. The voltage on the control gate is capacitively coupled to the floating gate, so a potential difference appears between the floating gate and the source, drain or channel region. This potential difference is used to change the charge on the floating gate.

In order to reduce the potential difference that has to be provided between the control gate and the source, drain or channel region, it is desirable to increase the capacitance between the control and floating gates relative to the capacitance between the floating gate and the source, drain or channel region. More particularly, it is desirable to increase the “gate coupling ratio” GCR defined as CCG/(CCG+CSDC) where CCG is the capacitance between the control and floating gates and CSDC is the capacitance between the floating gate and the source, drain or channel region. In one approach, the top portion of the oxide filling the STI structures is recessed so as to allow the floating gates to have a wider extent, and thereby increase the coupling ratio.

New and improved techniques to increase the gate coupling ratio are desired.

### SUMMARY

This section is a brief summary of some features of the invention. The invention is defined by the appended claims which are incorporated into this section by reference.

According to one embodiment of the present invention, a process for manufacturing an integrated circuit using shallow trench isolation (STI) includes a 2-step nitride removal process which provides, when combined with a nitride pull-back step, high coupling ratio and reduction in thinning of the tunnel oxide layer in a floating gate memory integrated circuit,.

In one embodiment, a nitride layer is provided over a pad oxide layer on a semiconductor substrate. The nitride layer is patterned so that trenches into the semiconductor substrate can be formed by an etching through the nitride layer and the oxide layer into the semiconductor substrate. A nitride pull-back step may then be performed. The trench is then filled with a dielectric material (e.g., a high density plasma oxide). A planarization step then exposes the nitride layer and a top portion of the dielectric material of the trench. A top portion of the nitride layer is then removed using a well-controlled timed etch step. Wet etch can be performed using, for example, a buffered oxide etch, such that a portion of the dielectric material (in this instance, oxide) is recessed from the exposed surface of the nitride layer. This oxide etch is performed with the exposed nitride layer protecting the corner region of the trench. The remaining exposed nitride layer is then removed

Other features are described below. The present invention is better understood upon consideration of the detailed description with the accompanying drawings.

### BRIEF DESCRIPTION OF THE DRAWINGS

FIGS. 1-6 show exemplary steps in an integrated circuit manufacturing process in accordance with one embodiment of the present invention.

FIG. 7 shows an example split gate flash memory array that can be manufactured using the 2-step nitride removal method of the present invention.

### DESCRIPTION OF PREFERRED EMBODIMENTS

This section describes some embodiments to illustrate the invention. The invention is not limited to these embodiments. The materials, conductivity types, layer thicknesses and other dimensions, circuit diagrams, and other details are given for illustration and are not limiting. In the detailed description below, the present invention is described for illustration purpose only by an application in a manufacturing process for a non-volatile memory integrated circuit. However, the present invention is applicable not only to manufacturing processes for non-volatile memory integrated circuits, it is applicable to most manufacturing processes of integrated circuits, including logic integrated circuits, and dynamic memory (e.g., DRAMs) and static memory (e.g., SRAMs) integrated circuits.

A memory array fabrication starts with substrate isolation. FIGS. 2-6 illustrate steps in an integrated circuit manufacturing process that uses a 2-step nitride removal process, in accordance with one embodiment of the present invention. These figures illustrate, for example, one variation that can be practiced in memory technology. Where conventional steps are mentioned below, their details may be found, for example, in U.S. Pat. No. 6,355,524 (the “'524 Patent”), entitled “Non-volatile Memory Structures and Fabrication Methods,” issued Mar. 12, 2002 to H. T. Tuan et al., or in U.S. Pat. No. 6,743,675 (the “'675 Patent”), entitled “Floating Gate Memory Fabrication Methods Comprising a Field Dielectric Etch with a Horizontal Etch Component,” issued on Jun. 1, 2004 to Ding. The '524 Patent and the '675 Patent are hereby incorporated by reference to provide background information.

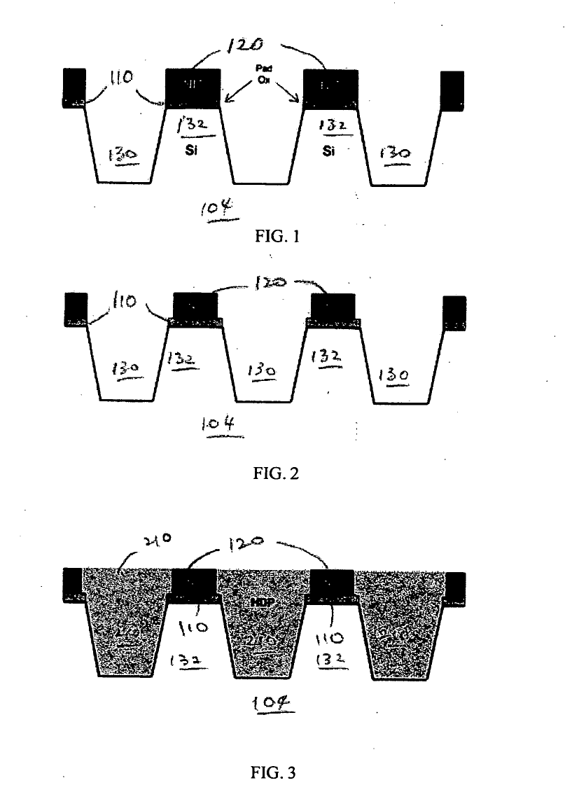

In this embodiment, field dielectric regions are fabricated by shallow trench isolation (“STI”) technology. Initially, as shown in FIG. 1, a P-type doped region is formed in a monocrystalline semiconductor substrate 104. Silicon dioxide 110 (pad oxide) is then formed on substrate 104 by thermal oxidation or another suitable technique. Silicon nitride 120 is then deposited on silicon oxide 110 and patterned photolithographically, using a photoresist mask (not shown) to define shallow isolation trenches 130. Silicon nitride 120, silicon oxide 110 and substrate 104 are then etched through the openings of the photoresist mask. Trenches 130 (“STI trenches”) are formed in the substrate as a result (FIG. 1). An exemplary depth of trenches 130 is about 0.2-0.3 μm measured from the top surface of the substrate 104. Other depths are possible. Trenches 130 will be filled with dielectric to provide isolation between active areas 132 of substrate 104. In FIG. 2, the trenches have sloping sidewalls, and the trenches are wider at the top than at the bottom. In some embodiments, the trenches have vertical sidewalls, or the trenches are wider at the bottom. The invention is not limited by any shape of the trenches.

Silicon nitride 120 is then subjected to a wet etch (e.g., HF/glycerol) to recess or “pull back” the vertical edges of the nitride/pad oxide layers away from trenches 130. See FIG. 2. This step reduces the aspect ratio of the holes that will be filled with dielectric 210 (these holes are formed by the openings in nitride 120 and oxide 10 and by the trenches 130). The lower aspect ratio facilitates filling these holes.

A thick layer 210.1 of silicon dioxide (e.g., 100-200 Å) is thermally grown on the exposed silicon surfaces to round the edges of trenches 130. Silicon dioxide 210.2 is then deposited by a high density plasma (HDP) process. Silicon oxide 210.2 fills the trenches and initially covers the nitride 120. Silicon oxide 210.2 is also referred to as “HDP oxide” by those skilled in the art. The Silicon oxide 210.2 may be polished by a CMP process that stops on nitride 120. A planar top surface may thus be provided (FIG. 3).

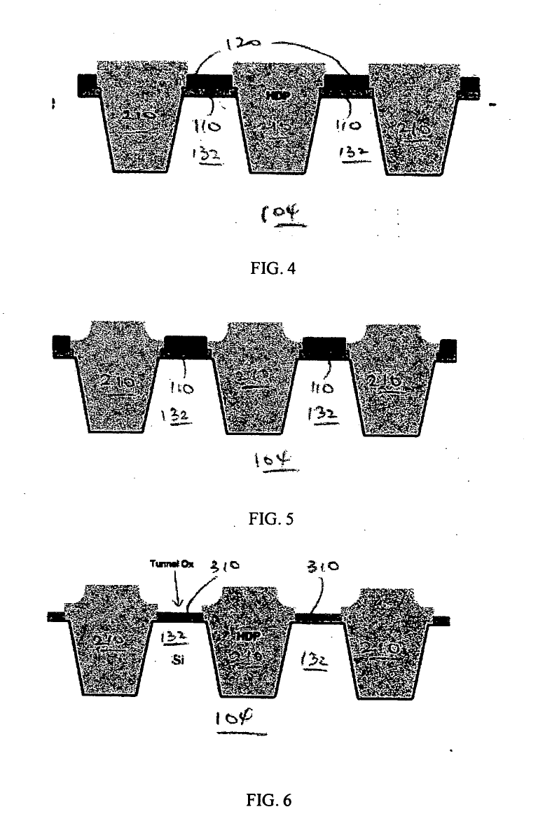

The layers 210.1, 210.2 are shown as a single layer 210. This dielectric silicon oxide 210 will be referred to as STI dielectric or, more generally, field dielectric. Silicon nitride 120 is then removed using a timed etch in a well-controlled nitride etch rate bath, such as a phosphoric acid bath (FIG. 4). Note that, by using a timed etch in a well-controlled nitride etch rate bath, it is not necessary to provide a stopping layer of oxide.

Next, a wet etch of silicon oxide is performed to etch silicon oxide 210 (FIG. 5). The wet etch can be performed using, for example, an isotropic wet etch selective to silicon nitride. A buffered oxide etch or a dilute HF (DIF) etch may be used, for example. The wet etch recesses the surface of the field dielectric away from the exposed nitride layer.

A second nitride etch step is then performed to remove the remaining silicon nitride 120 using, for example, phosphoric acid. This method provides an increase in area at the top of the field dielectric layer—hence, a high coupling ratio will be achieved in a floating gate device—without requiring an additional masking step. At the same time, the oxide etch is carried out while the STI corner region is protected by the nitride and the pad oxide. This protection reduces subsequent thinning of the tunnel oxide.

Pad oxide layer 110 is then removed to expose the silicon surface. As shown in FIG. 6, silicon dioxide 310 (tunnel oxide) is thermally grown on the exposed areas of substrate 104. An exemplary thickness of tunnel oxide 310 is about 80-100 Å.

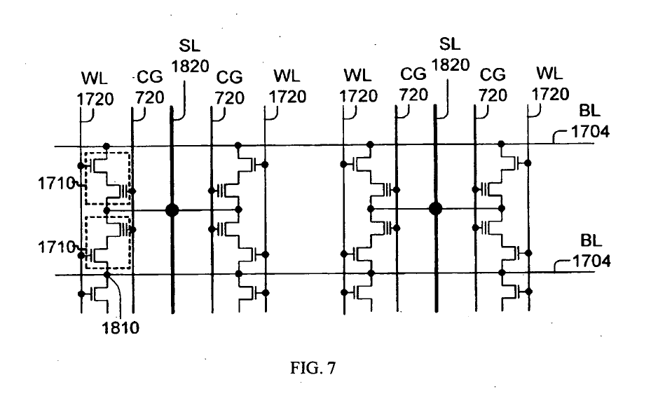

A wide range of floating gate memories (e.g., NAND, NOR or AND type flash memories) can be made using the teachings of the present invention, including stacked gate, split gate and other cell structures, flash and non-flash EEPROMs, and other memory types. An example split gate flash memory array is illustrated in FIG. 7. This memory array is similar to one disclosed in the aforementioned '524 Patent.

Fabrication of the non-volatile memory integrated circuit may be completed using the steps shown and discussed in conjunction with FIGS. 16-50 (e.g., col. 11, lines 48 et seq,) in the aforementioned '524 Patent. Alternatively, the remaining fabrication steps can follow that shown and discussed in FIGS. 14-19B and incorporated by reference from the '675 Patent.

The above detailed description is provided to illustrate the specific embodiments of the present invention and is not intended to be limiting. Numerous variations and modifications within the scope of the present invention are possible. The present invention is set forth in the appended claims.

We claim:

1. A method for manufacturing an integrated circuit, comprising:
Providing a nitride layer over a semiconductor substrate;
Patterning the surface of the nitride layer;
etching through the nitride layer to the semiconductor substrate to create a trench in the silicon substrate;
filling the trench with a dielectric material, and further processing such that the nitride layer and a top portion of the dielectric material of the trench are exposed;
removing a top portion of the exposed nitride layer;
removing the top portion of the dielectric material from the trench; and
removing the remainder of the exposed nitride layer.

2. A method as in claim 1, further comprising, between etching through the nitride layer and filling the trench, etching a sidewall portion of the nitride layer.

3. A method as in claim 1, wherein the top portion of the exposed nitride layer is removed using a timed isotropic etch.

4. A method as in claim 3, wherein the timed isotropic etch is achieved using phosphoric acid.

5. A method as in claim 1, wherein the top portion of the dielectric material is performed using a wet oxide etch.

6. A method as in claim 1, wherein the dielectric material comprises a high density plasma oxide.

7. A method as in claim 1, further comprising, prior to providing the nitride layer, providing a layer of oxide over the substrate.

8. A method as in claim 1, wherein the further processing comprises chemical mechanical polishing.

9. A method as in claim 1, further comprising, subsequent to removing the remainder of the exposed nitride layer, thermally growing a layer of tunnel oxide.
